(19) United States
(12) Patent Application Publication
(10) Pub. No.: US 2026/0319348 A1
(43) Pub. Date: Oct. 15, 2026

(54) HEAT DISSIPATION DEVICE

(71) Applicant: Qisda Corporation, Taoyuan City (TW)

(72) Inventors: Hsin-Jung YEH, Taoyuan City (TW); Chun-Ming SHEN, Taoyuan City (TW)

(73) Assignee: Qisda Corporation, Taoyuan City (TW)

(21) Appl. No.: 19/466,711

(22) Filed: Feb. 2, 2026

(30) Foreign Application Priority Data
Feb. 21, 2025 (CN) 202510197619.4

(51) Int. Cl. G03B 21/16; H05K 7/20

(52) U.S. Cl. CPC G03B 21/16; H05K 7/2039

(57) ABSTRACT

A heat dissipation device for cooling an optical engine of a projection module. The heat dissipation device includes a housing, a heat sink, a shielding member and a fixing member. The housing has an accommodation space for accommodating the optical engine. The heat sink has a first portion in thermal contact with the housing and a second portion separated from the housing by a gap, the gap is connected to the accommodation space, and the heat generated by the optical engine is conducted through the first portion of the heat sink and the housing. The shielding member covers the housing, the second portion and the gap. The fixing member passes through the shielding member, the second portion of the heat sink and the housing in sequence, and is used to fix the shielding member and the heat sink to one side of the housing.

This application claims the benefit of People’s Republic of China application Serial No. 202510197619.4, filed Feb. 21, 2025, the subject matter of which is incorporated herein by reference.

### BACKGROUND OF THE INVENTION

### Field of the Invention

The invention relates in general to a heat dissipation device, and more particularly to a heat dissipation device for cooling an optical engine of a projection module.

### Description of the Related Art

Generally speaking, when an optical engine is in operation, it will project discarded light onto the cover of the optical engine, so that the projected light appears dark. However, the temperature inside the optical engine is relatively high, which will cause the optical engine to expand due to heat, and easily cause displacement of optical elements. In addition, a conventional heat dissipation device is arranged on the housing of the optical engine through a heat insulating sheet to absorb the waste heat of discarded light generated by the optical engine. The heat dissipation device is installed outside the optical engine or clamped in a housing opening of the optical engine, and the heat dissipation device is thermally insulated from the optical engine to prevent the waste heat from being transferred back to the housing of the optical engine. However, since the heat dissipation device is not in thermal contact with the optical engine housing, the heat dissipation efficiency cannot be effectively improved.

### SUMMARY OF THE INVENTION

The present invention relates to a heat dissipation device for improving the heat dissipation efficiency of a projection module.

According to one aspect of the present invention, a heat dissipation device is provided for cooling an optical engine of a projection module. The heat dissipation device includes a housing, a heat sink, a shielding member and a fixing member. The housing has an accommodating space for accommodating the optical engine. The heat sink has a first portion in thermal contact with the housing and a second portion separated from the housing by a gap, the gap is connected to the accommodating space, and the heat generated by the optical engine is conducted through the first portion of the heat sink and the housing. The shielding member covers the housing, the second portion and the gap. The fixing member passes through the shielding member, the second portion of the heat sink and the housing in sequence, and is used to fix the shielding member and the heat sink to one side of the housing.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 is a schematic diagram of a projection module according to an embodiment of the present invention.

FIG. 2 is a schematic diagram of an exploded view of a heat dissipation device in FIG. 1.

FIG. 3 is a schematic diagram of the A-A section of the projection module in FIG. 1.

FIG. 4 is a partial enlarged view of the portion B in FIG. 3.

### DETAILED DESCRIPTION OF THE INVENTION

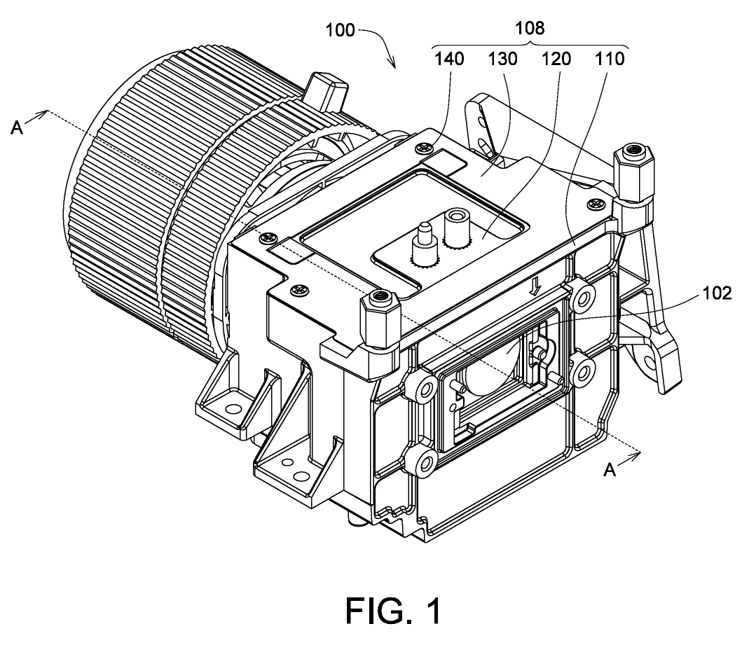

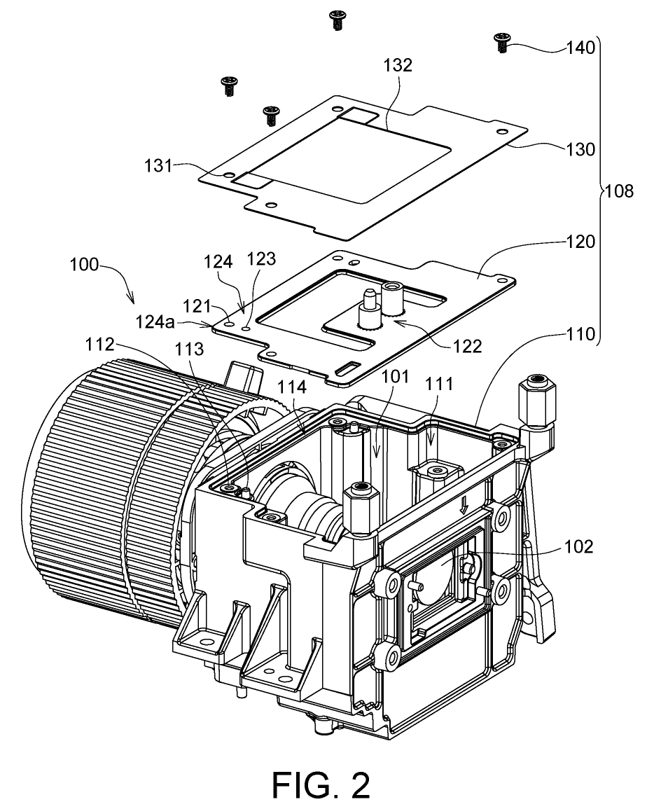

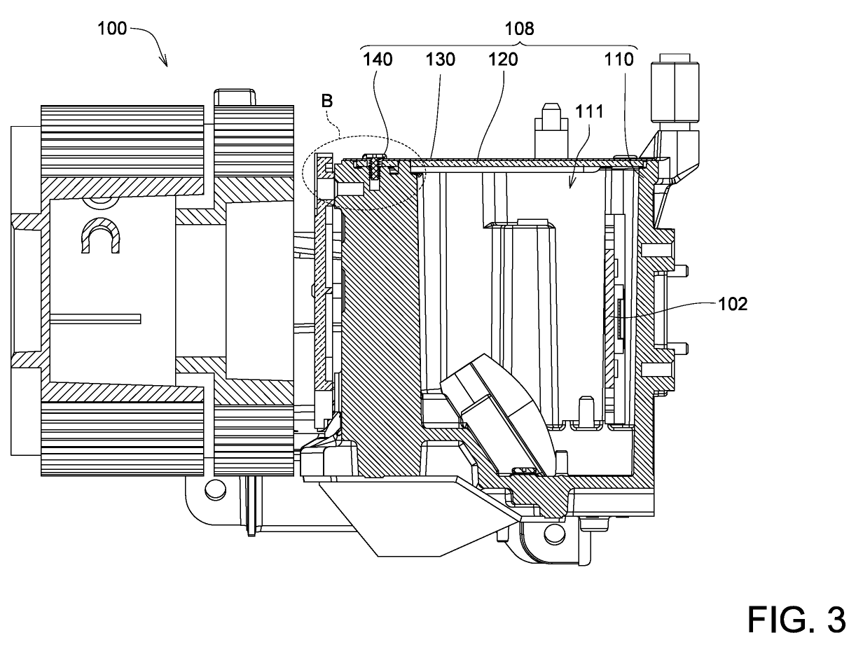

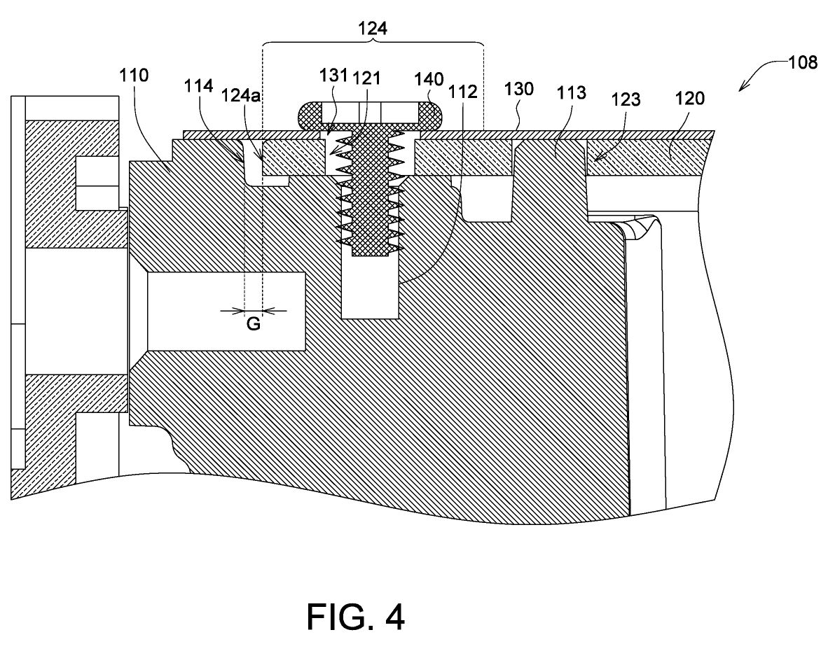

Referring to FIGS. 1-4, FIG. 1 is a schematic diagram of a projection module 100 according to an embodiment of the present invention, FIG. 2 is a schematic diagram of an exploded view of a heat dissipation device 108 in FIG. 1, FIG. 3 is a schematic diagram of the A-A section of the projection module 100 in FIG. 1, and FIG. 4 is a partial enlarged view of the portion B in FIG. 3.

The projection module 100 may include an optical engine 101, an optical valve 102, and a heat dissipation device 108. The optical engine 101 is suitable for generating an image light. The optical valve 102 is disposed downstream of the optical engine 101 and converts the beam into a first beam portion (i.e., image light) and a second beam portion (i.e., discarded beam). The prism assembly (not shown) is disposed in the optical path downstream of the optical valve 102 and can receive the image light and the discarded beam. The heat dissipation device 108 is disposed in the optical path downstream of the prism assembly and is used to shield the discarded beam from the prism assembly. Thus, the heat dissipation device 108 irradiated by the discarded light beam can conduct heat energy through the heat sink 120 to effectively reduce the temperature in the optical engine 101, and reduce or avoid the phenomenon of thermal drift of the projection module 100. In addition, the heat dissipation device 108 can not only reduce the temperature in the optical engine 101, but also covers the heat sink 120 with the shielding member 130, which has a dustproof function.

Referring to FIG. 2, the heat dissipation device 108 is configured to cool the optical engine 101. The heat dissipation device 108 includes a housing 110, a heat sink 120, a shielding member 130 and a fixing member 140. The number of fixing members 140 may include but is not limited to four. The fixing member 140 is configured to fix the shielding member 130 and the heat sink 120 to one side of the housing 110, as shown in FIG. 1. In one embodiment, the fixing member 140 is, for example, a fastener such as a screw. However, the fixing member 140 may also be a riveted member or a clamping member such as a rivet or a latch, and the present invention is not limited thereto.

The housing 110 has an accommodating space 111 inside for accommodating the optical engine 101. In addition, the light valve 102 is a spatial light modulator, such as a digital micro-mirror device (DMD). However, in other embodiments, the light valve 102 may also be a liquid-crystal-on-silicon panel (LCOS panel), a transmissive liquid crystal panel, or other suitable forms of light valve modules, and the present invention is not limited thereto.

The heat sink 120 has a first portion 122 in thermal contact with the housing 110 and a second portion 124 separated from the housing 110 by a gap G. The first portion 122 may be located at the center of the heat sink 120, and the second portion 124 may be located at the peripheral portion of the heat sink 120. However, the present invention is not limited thereto. In another embodiment, the first portion 122 may be located at the edge of the heat sink 120, not limited to the center of the heat sink 120. The first portion 122 is configured to absorb the heat generated by a discarded beam projected by the optical engine 101.

Referring to FIG. 2, the second portion 124 of the heat sink 120 is arranged around the first portion 122, and the housing 110 has a sidewall portion 114, and the second portion 124 is horizontally opposite to the sidewall portion 114 and separated by a predetermined gap G (refer to FIG. 4). The sidewall portion 114 is, for example, located on the peripheral structure of the housing 110 surrounding the accommodation space 111.

Referring to FIG. 2, the shielding member 130, for example, has an opening 132 for exposing a portion of the heat sink 120. The shape of the opening 132 may include, but is not limited to, a quadrilateral. As shown in FIG. 2, the first portion 122 of the heat sink 120 is embedded in the opening 132 of the shielding member 130 so that the first portion 122 of the heat sink 120 is exposed in the opening 132 of the shielding member 130. The first portion 122 of the heat sink 120 can be used to shield the discarded beam and absorb the heat generated from the discarded beam. The heat sink 120 conducts the heat to outside by, for example, heat radiation or heat convection to achieve the effect of cooling the optical engine 101.

As shown in FIG. 2, the peripheral structure of the housing 110 surrounding the accommodating space 111 is provided with a plurality of screw holes 112. The number of screw holes 112 is not limited. The position of the screw holes 112 is corresponding to the position of the fixing member 140 so that each fixing member 140 can pass through the opening 131 of the shielding member 130, the through-hole 121 of the heat sink 120 and the corresponding screw hole 112 and be fixed on the housing 110.

In addition, referring to FIG. 2, the peripheral structure of the housing 110 surrounding the accommodating space 111 is also provided with a plurality of positioning posts 113, and the number of the positioning posts 113 is not limited. The surrounding portion of the heat sink 120 is correspondingly provided with a plurality of positioning holes 123, and the number of the positioning holes 123 is not limited. The positions of the positioning holes 123 are corresponding to the positions of the positioning posts 113, so that each positioning post 113 can pass through the corresponding positioning hole 123 to keep the positions of the heat sink 120 and the housing 110 fixed.

The portion of the heat sink 120 that contacts the surrounding of the screw hole 112 of the housing 110 can also be regarded as a portion in thermal contact with the housing 110, so that the heat absorbed by the heat sink 120 can be conducted to the housing 110 through the surrounding portion, and then the housing 110 conducts the heat to the external air by means of thermal radiation or thermal convection, so as to further achieve the effect of cooling the optical engine 101.

In addition, referring to FIG. 2, the sidewall portion 114 of the housing 110 is adjacent to the periphery of the screw hole 112, and the periphery of the through-hole 121 of the heat sink 120 may be the second portion 124, and the edge surface 124a of the second portion 124 is horizontally opposite to the sidewall portion 114 and is separated by a gap G (see FIG. 4). The edge surface 124ais not in direct contact with the housing 110, and therefore, the edge surface 124a of the second portion 124 is separated from the housing 110 by a gap G.

From a top view, the second portion 124 of the heat sink 120 and the sidewall portion 114 do not overlap in the vertical projection direction. The shielding member 130 may be attached to one side of the second portion 124 and the sidewall portion 114 by adhesive, and the shielding member 130 extends substantially horizontally to one side of the housing 110 and is in the shape of a sheet.

In one embodiment, the gap G is configured to connect with the accommodation space 111. Referring to FIGS. 2 and 4, the shielding member 130 covers the housing 110, the second portion 124 and the gap G. The fixing member 140 can be fixed to the housing 110 by sequentially passing through the opening 131 of the shielding member 130, the through-hole 121 of the second portion 124 of the heat sink 120 and the screw hole 112 of the housing 110 to prevent dust from entering the accommodating space 111 through the gap G.

The shielding member 130 is, for example, a sheet. The shielding member 130 is, for example, a rubber sheet or a polyester film (for example, a polyethylene terephthalate (PET) film). In addition to preventing dust, the shielding member 130 also has a light-blocking effect, which can prevent light from leaking from the edge of the housing 110. The projection module 100 of the present invention can avoid the problem of poor heat dissipation efficiency caused by the traditional heat dissipation device being arranged on the housing of optical engine through the heat insulation sheet through the above-mentioned heat dissipation device 108. In contrast, the heat dissipation device 108 of the present embodiment is in thermal contact with the housing 110, so that the heat dissipation efficiency can be effectively improved.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A heat dissipation device for cooling an optical engine of a projection module, the heat dissipation device comprising:
a housing having an accommodation space for accommodating the optical engine;
a heat sink having a first portion in thermal contact with the housing and a second portion separated from the housing by a gap, the gap being in communication with the accommodation space, and a heat generated by the optical engine being conducted through the first portion of the heat sink and the housing;
a shielding member covering the housing, the second portion and the gap; and
a fixing member passing through the shielding member, the second portion of the heat sink and the housing in sequence, for fixing the shielding member and the heat sink to one side of the housing.

2. The heat dissipation device as claimed in claim 1, wherein the shielding member is in a form of a sheet.

3. The heat dissipation device as claimed in claim 1, wherein the shielding member is a rubber sheet or a polyester film.

4. The heat dissipation device as claimed in claim 1, wherein the fixing member is a locking member.

5. The heat dissipation device as claimed in claim 1, wherein the fixing member is a rivet or a clamping member.

6. The heat dissipation device as claimed in claim 1, wherein the first portion of the heat sink is embedded in an opening of the shielding member, the second portion includes a through hole, and the fixing member passes through the through hole and is fixed to the housing.

7. The heat dissipation device as claimed in claim 6, wherein the second portion of the heat sink is arranged around the first portion, the housing has a sidewall portion, and the second portion is horizontally opposite to the sidewall portion and separated by the gap.

8. The heat dissipation device as claimed in claim 7, wherein the second portion and the sidewall portion do not overlap in a vertical projection direction.

9. The heat dissipation device as claimed in claim 7, wherein the shielding member is attached to one side of the second portion and the sidewall portion.

10. The heat dissipation device as claimed in claim 1, wherein the first portion is configured to absorb heat generated by a discarded beam projected by the optical engine.

11. A projection module, comprising:
an optical engine;
a housing having an accommodation space for accommodating the optical engine;
a heat sink having a first portion in thermal contact with the housing and a second portion separated from the housing by a gap, the gap being in communication with the accommodation space, and a heat generated by the optical engine being conducted through the first portion of the heat sink and the housing;
a shielding member covering the housing, the second portion and the gap; and
a fixing member passing through the shielding member, the second portion of the heat sink and the housing in sequence, for fixing the shielding member and the heat sink to one side of the housing.

12. The projection module as claimed in claim 11, wherein the shielding member is in a form of a sheet.

13. The projection module as claimed in claim 11, wherein the shielding member is a rubber sheet or a polyester film.

14. The projection module as claimed in claim 11, wherein the fixing member is a locking member.

15. The projection module as claimed in claim 11, wherein the fixing member is a rivet or a clamping member.

16. The projection module as claimed in claim 11, wherein the first portion of the heat sink is embedded in an opening of the shielding member, the second portion includes a through hole, and the fixing member passes through the through hole and is fixed to the housing.

17. The projection module as claimed in claim 16, wherein the second portion of the heat sink is arranged around the first portion, the housing has a sidewall portion, and the second portion is horizontally opposite to the sidewall portion and separated by the gap.

18. The projection module as claimed in claim 17, wherein the second portion and the sidewall portion do not overlap in a vertical projection direction.

19. The projection module as claimed in claim 17, wherein the shielding member is attached to one side of the second portion and the sidewall portion.

20. The projection module as claimed in claim 11, wherein the first portion is configured to absorb heat generated by a discarded beam projected by the optical engine.
